(19) United States
(12) Patent Application Publication
(10) Pub. No.: US 2026/0173397 A1
(43) Pub. Date: Jun. 18, 2026

(54) FERROELECTRIC NOR MEMORY ARCHITECTURES

(71) Applicant: Micron Technology, Inc., Boise, ID (US)

(72) Inventors: Lorenzo Fratin, Buccinasco (IT); Fabio Pellizzer, Boise, ID (US)

(21) Appl. No.: 19/399,371

(22) Filed: Nov. 24, 2025

Related U.S. Application Data
(60) Provisional application No. 63/734,615, filed on Dec. 16, 2024.

(51) Int. Cl. H10B 51/30; H10B 51/10; H10B 51/20

(52) U.S. Cl. CPC H10B 51/30; H10B 51/10; H10B 51/20

(57) ABSTRACT

Methods, systems, and devices for ferroelectric NOR memory architectures are described. The ferroelectric NOR memory architecture may include a first pillar, a second pillar, and a third pillar positioned between the first and second pillars. The memory device may include multiple first memory cells positioned between a respective first word line and a first semiconductor material at a first side of the third pillar and multiple second memory cells positioned between a respective second word line and the first semiconductor material at a second side of the third pillar. The memory device may include multiple first portions and second portions of a second semiconductor material, where each first portion couples a respective first memory cell and a respective second memory cell to the first pillar, and where each second portion couples a respective first memory cell and a respective second memory cell to the second pillar.

### CROSS REFERENCE

The present Application for Patent claims priority to U.S. Patent Application No. 63/734,615 by Fratin et al., entitled “FERROELECTRIC NOR MEMORY ARCHITECTURES,” filed Dec. 16, 2024, which is assigned to the assignee hereof, and which is expressly incorporated by reference in its entirety herein.

### TECHNICAL FIELD

The following relates to one or more systems for memory, including ferroelectric NOR memory architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports ferroelectric NOR memory architectures in accordance with examples as disclosed herein.

FIGS. 2A and 2B show examples of an architecture that supports FeNOR memory architectures in accordance with examples as disclosed herein.

FIGS. 3A, 3B, 3C, 3D, and 3E show examples of fabrication operations that support FeNOR memory architectures in accordance with examples as disclosed herein.

FIGS. 4A and 4B an example of an architecture that supports FeNOR memory architectures in accordance with examples as disclosed herein.

FIG. 5 shows a flowchart illustrating a method or methods that support FeNOR memory architectures in accordance with examples as disclosed herein.

### DETAILED DESCRIPTION

Some memory devices may implement a ferroelectric material in memory cells that are arranged Not-AND (NAND) architecture, such as a three-dimensional (3D) or vertical NAND architecture. For example, a ferroelectric material may be implemented in addition to a charge-trapping material, or instead of a charge trapping material, of a memory cell that alters (e.g., in accordance with a stored logic state, in accordance with a stored electric field) an activation voltage for a semiconductor channel associated with the memory cell (e.g., a channel associated with a stack or memory cells, a channel associated with a pillar of memory cells). In some examples, a memory device with such an implementation of a ferroelectric material may experience relatively faster programming (e.g., in accordance with a polarization change of the ferroelectric material, in accordance with a change in dipole polarization) or relatively lower power consumption (e.g., by reducing or avoiding electron transfer associated with a charge trapping material, with relatively lower write voltages) than a memory device with other implementations of charge-trapping materials. However, some implementations of ferroelectric material in a memory array may have other performance tradeoffs. For example, some implementations of a ferroelectric material in such architectures may be associated with relatively high read latency, a relatively high erase latency, or both (e.g., due to relatively low current in vertical channels of a 3D NAND array, due to a relatively high capacitance of planar word lines implemented in a 3D NAND array, or both).

In accordance with the techniques described herein, ferroelectric memory cells may be implemented in accordance with a Not-OR (NOR) architecture (e.g., a FeNOR (FeNOR) architecture, a 3D FeNOR architecture), in which each memory cell along a column of the NOR architecture may be connected with (e.g., between) vertical source lines and bit lines (e.g., also referred to as drain lines). For example, a memory array implementing a FeNOR architecture may include first pillars (e.g., conductive pillars, conductors, each associated with a first access line, such as a bit line or source line), second pillars (e.g., conductive pillars, conductors, each associated with a second access line, such as a bit line or drain line), and third pillars each positioned between respective first and second pillars. Each of the third pillars may include a first semiconductor material that extends along the third pillar (e.g., along a length direction, along a height direction). The memory array may also include multiple first memory cells (e.g., associated with first transistors including a ferroelectric material) along a given third pillar that are each positioned between a respective first word line and the first semiconductor material at a first side of the third pillar, and multiple second memory cells (e.g., associated with second transistors including a ferroelectric material) along the given third pillar that are each positioned between a respective second word line and the first semiconductor material at a second side of the third pillar. To form semiconductor channels associated with the first and second memory cells (e.g., between a first pillar and a second pillar), the memory device may include multiple portions of a second semiconductor material (e.g., having a different doping configuration than the first semiconductor material) between the first semiconductor material and each of the respective first and second pillars. Thus, an FeNOR memory array may include stacks of memory cells (e.g., along one or more sides of a given pillar of memory cells), which may be configured to support an improved balance of read latency, write latency, power consumption, and storage volatility compared with other implementations and architectures.

In addition to applicability in memory systems as described herein, techniques for FeNOR architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by providing for an increased quantity of memory cells (e.g., NOR memory cells) arranged in a pier and pillar architecture, which may decrease latency associated with read and programming operations, improve random access speeds, and reduce power consumption, among other benefits.

Features of the disclosure are illustrated and described in the context of memory devices and related circuitry. Features of the disclosure are further illustrated and described in the context of architectures, memory devices, and flowcharts.

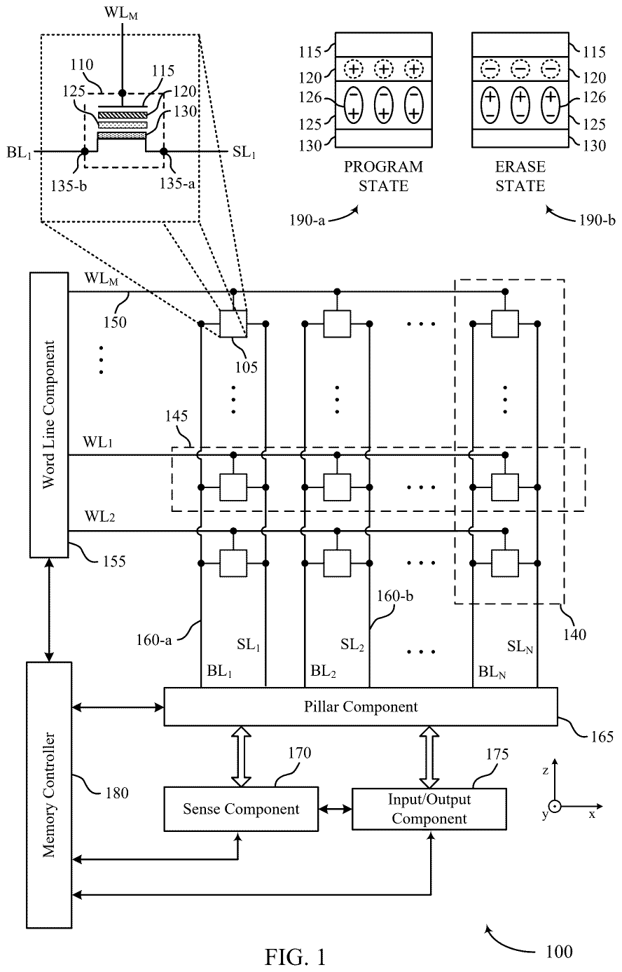

FIG. 1 shows an example of a memory device 100 that supports FeNOR memory architectures in accordance with examples as disclosed herein. The memory device 100 may be referred to as a memory die or an electronic memory apparatus, and include one or more arrays of memory cells 105. FIG. 1 is an illustrative representation of various components and features of the memory device 100. As such, the components and features of the memory device 100 are shown to illustrate functional relationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features. Aspects of the memory device 100 may be described with reference to an x-direction, a y-direction, and a z-direction of the illustrated coordinate system.

A memory device 100 may implement non-volatile memory cells that are based on ferroelectric properties of various materials, such as dopant-free hafnium oxide (HfOx) or hafnium zirconium oxide (HfZrOx), among other examples. Such memory cells may be referred to as ferroelectric field-effect transistor (Fe-FETs) memory cells and may, in some examples, be implemented in a NAND architecture (e.g., 3D NAND architecture) by replacing or combining a charge-trapping material in a gate dielectric stack with a ferroelectric material. Compared with a charge-trapping material, which may store an electric field based on electron transfer into or out of the charge-trapping material (e.g., by way of hot electron tunneling, by way of Fowler-Nordheim (FN) tunneling), a ferroelectric material may store an electric field by way of polarization (e.g., a dipole polarization, a polarization orientation, a dipole orientation, an electric field orientation, with or without an accompanying electron transfer) of the ferroelectric material, which may be associated with a switching mechanism of ferroelectric dipoles of the ferroelectric material. In some examples, such an implementation may support relatively faster programming (e.g., in accordance with a polarization change of the ferroelectric material) or relatively lower power consumption than a memory device with other implementations of charge-trapping materials or NAND architectures (e.g., associated with a reduction of electron transfer to write or erase a given logic state, associated with relatively lower voltages to induce a dipole polarization than perform charge transfer). However, some such implementations of ferroelectric material may have other performance tradeoffs. For example, some implementations of a ferroelectric material in such architectures may be associated with relatively high read latency, a relatively high erase latency, or both (e.g., due to relatively low current in vertical channels of a 3D NAND array, due to a relatively high capacitance of planar word lines implemented in a 3D NAND array, or both), or may prevent byte alterability (e.g., due to an erase granularity being different than a write granularity), among other drawbacks.

In accordance with the techniques described herein, to improve performance of memory cells 105 within a dense array, the memory device 100 may implement a NOR structure, where each memory cell 105 along a column of the array may be connected to vertical source lines and bit lines (e.g., otherwise referred to as drain lines, along the z-direction). For example, the memory device 100 may implement an architecture that integrates a relatively high-density array of Fe-FETs in a NOR configuration, thereby enabling the memory device 100 to realize improved read and program performance, relatively quicker random-access procedures, relatively improved byte alterability, and experience reduced power consumption (e.g., lower energy) for a variety of applications.

For example, the memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array (e.g., a memory array) of the memory device 100, where, in some examples, an array may refer to a contiguous set of memory cells 105 (e.g., a contiguous set of elements of a semiconductor chip).

Each memory cell 105 may be implemented as a transistor (e.g., an Fe-FET) that is configured for storing an electric field representative of a logic state. For example, the blow-up of FIG. 1 illustrates a memory cell 105 (e.g., an FeNOR memory cell, an FeFET memory cell, a ferroelectric memory cell) that includes a transistor 110 that may be used to store a logic value. The transistor 110 may include a gate 115 (e.g., a gate portion, a control gate), a dielectric portion 120 (e.g., a gate dielectric), a ferroelectric portion 125 (e.g., a polarization portion, a portion including ferroelectric dipoles 126, a portion for storing an electric field corresponding to a logic state), a channel interlayer portion (not shown), and a channel portion 130 (e.g., including one or more semiconductor material portions, a doped semiconductor channel). The transistor 110 also may include a first node 135-a (e.g., a source or drain associated with the channel portion 130) and a second node 135-b (e.g., a drain or source associated with the channel portion 130). An electric field stored at a memory cell 105 (e.g., stored at least in part by a polarization of a ferroelectric portion 125) may affect the threshold voltage of the transistor 110 (e.g., a voltage at a gate 115 to activate the channel portion 130, an activation voltage), thereby affecting an amount of current that may through the transistor 110 when the gate 115 is biased (e.g., when a voltage is applied to the gate 115, when a voltage is applied to a word line 150, when the memory cell 105 is read).

A logic value may be stored in a memory cell 105 (e.g., in a transistor 110) by inducing (e.g., writing, storing) an electric field in the memory cell 105. For example, an electric field corresponding to a logic state may be stored based at least in part on storing a polarization (e.g., a dipole polarization, a polarization orientation, a dipole orientation, a local electric field orientation) in a ferroelectric portion 125, where different polarizations may correspond to different logic states. For example, a memory cell 105 may be written with a cell state 190 (e.g., an electric field state, a polarization state, a written state, corresponding to a logic state), such as either a cell state 190-a (e.g., a “PROGRAM” state) or a cell state 190-b (e.g., an “ERASE” state). In the illustrated examples, a cell state 190-a may correspond to a first polarization of a ferroelectric portion 125 (e.g., a first orientation of dipoles 126, corresponding to a positive local electric field from a gate 115 to a channel portion 130), and a cell state 190-b may correspond to a second polarization of a ferroelectric portion 125 (e.g., a second orientation of dipoles 126, corresponding to a negative local electric field from a gate 115 to a channel portion 130). In some examples, the cell state 190-a may be associated with supporting a relatively lower voltage at a gate 115 to activate a channel portion 130 (e.g., a relatively higher activation voltage, a relatively lower conductivity through the channel portion 130 for a given voltage at the gate 115), whereas the cell state 190-b may be associated with supporting a relatively higher voltage at a gate 115 to activate a channel portion 130 (e.g., a relatively lower activation voltage, a relatively higher conductivity through the channel portion 130 for the given voltage at the gate 115).

In some examples, an electric field corresponding to a logic state may also be associated with storing an electric charge, such as by way of electron transfer into or out of a portion of the memory cell 105 (e.g., a dielectric portion 120, a channel interlayer portion, a charge trapping material included in combination with a ferroelectric portion 125, the ferroelectric portion 125 itself, or a combination thereof). For example, an electric field associated with the cell state 190-a may also include a net positive charge (e.g., in addition to a polarization of a ferroelectric portion 125, as stored in a dielectric portion 120, as a result of transferring electrons from the memory cell 105, as a result of hole injection), and an electric field associated with the cell state 190-b may also include a net negative charge (e.g., in addition to a polarization of a ferroelectric portion 125, as stored in a dielectric portion 120, as a result of transferring electrons into the memory cell 105, as a result of electron injection).

In the example of memory device 100, the memory cells 105 may be configured in planes 145 (e.g., in an xy-plane, memory cells 105 arranged along the x-direction and the y-direction) and along pillars 140 (e.g., third pillars including memory cells 105 arranged along the z-direction). For example, a plane 145 of memory cells 105, or subset thereof, may be coupled with a respective word line 150 (e.g., WL₁ through WL_{M}, a planer word line, a word line comb), and each pillar 140 of memory cells 105 may be coupled with a respective bit line 160-a (e.g., BL₁ through BL_{N}) and a respective source line 160-b (e.g., SL₁ through SL_{N}). Each of the word lines 150, bit lines 160-a, and source lines 160-b may be an example of an access line of the memory device 100. In the example of memory device 100, one memory cell 105 may be located at the intersection of (e.g., coupled with, coupled between) a word line 150 and a paired bit line 160-a and source line 160-b. This intersection may be referred to as an address of a memory cell 105. A target (e.g., selected) memory cell 105 may be a memory cell 105 located at the intersection of an activated or otherwise selected word line 150 and an activated or otherwise selected bit line 160-a and source line 160-b.

The memory device 100 may include a 3D memory array, where multiple two-dimensional (2D) memory arrays (e.g., planes 145, in xy-planes) may be formed on top of one another (e.g., along the z-direction). In some examples, such an arrangement may increase the quantity of memory cells 105 that may be fabricated on a single die or substrate as compared with 2D arrays, which, in turn, may reduce production costs, or increase the performance of the memory array, or both. In the example of FIG. 1, memory device 100 includes multiple planes 145 (e.g., decks, layers, levels, tiers) of memory cells 105. The planes 145 (e.g., word lines 150) may, in some examples, be separated by an electrically insulating material. Each plane 145 may be aligned or positioned so that memory cells 105 may be aligned (e.g., exactly aligned, overlapping, or approximately aligned) with one another across each plane 145, forming a memory cell 105 stack along the z-direction (e.g., along a pillar).

Access operations such as reading, writing, rewriting, and refreshing may be performed on a memory cell 105 by activating (e.g., selecting) a word line 150, a bit line 160-a, and a source line 160-b coupled with the memory cell 105, which may include applying a voltage, a charge, or a current to the respective access line. After selecting a memory cell 105 (e.g., in a read operation), a resulting signal may be used to determine the logic state stored by the memory cell 105.

Accessing memory cells 105 may be controlled using a word line component 155 (e.g., a row decoder, a word line decoder), a pillar component 165 (e.g., a pillar decoder, a column decoder), or both, among other component architectures. For example, the word line component 155 may receive a row address from the memory controller 180 and activate a corresponding word line 150 based on the received row address. Similarly, the pillar component 165 may receive a column address from the memory controller 180 and activate a corresponding bit line 160-a and a corresponding source line 160-b.

In some examples, the memory controller 180 may control operations (e.g., read operations, write operations, rewrite operations, refresh operations) of memory cells 105 using one or more components (e.g., word line components 155, pillar components 165, sense components 170, input/output components 175). In some cases, one or more of the word line component 155, the pillar component 165, and the sense component 170 may be co-located with or otherwise included as part of the memory controller 180. The memory controller 180 may generate row and column address signals to activate a desired word line 150, bit line 160-a, and source line 160-b. The memory controller 180 may also generate or control various voltages or currents used during the operation of memory device 100.

A memory cell 105 may be written (e.g., programmed, set) by activating the relevant word line 150, bit line 160-a, and source line 160-b (e.g., via a memory controller 180). In other words, a logic state may be stored in a memory cell 105. A word line component 155, pillar component 165, or both may accept data, for example, via input/output component 175, to be written to the memory cells 105. In some examples, a write operation may be performed at least in part by a sense component 170, or a write operation may be configured to bypass a sense component 170.

A memory cell 105 may be read (e.g., sensed) by a sense component 170 when the memory cell 105 is accessed (e.g., in cooperation with the memory controller 180) to determine a logic state written to or stored by the memory cell 105. For example, the sense component 170 may be configured to evaluate a current or charge transfer through or from the memory cell 105, or a voltage resulting from coupling the memory cell 105 with the sense component 170, responsive to a read operation. The sense component 170 may provide an output signal indicative of the logic state read from the memory cell 105 to one or more components (e.g., to the pillar component 165, the input/output component 175, to the memory controller 180).

A sense component 170 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 170 may include a collection of circuit elements that are repeated for each of a set or subset of bit lines 160-a, source lines 160-b, or both that are coupled with the sense component 170. For example, a sense component 170 may include a separate sensing circuit (e.g., a separate or duplicated sense amplifier, a separate or duplicated signal development component) for each of a set of bit lines 160-a, each of a set of source lines 160-b, or both that are coupled with the sense component 170, such that a logic state may be separately detected for respective memory cells 105.

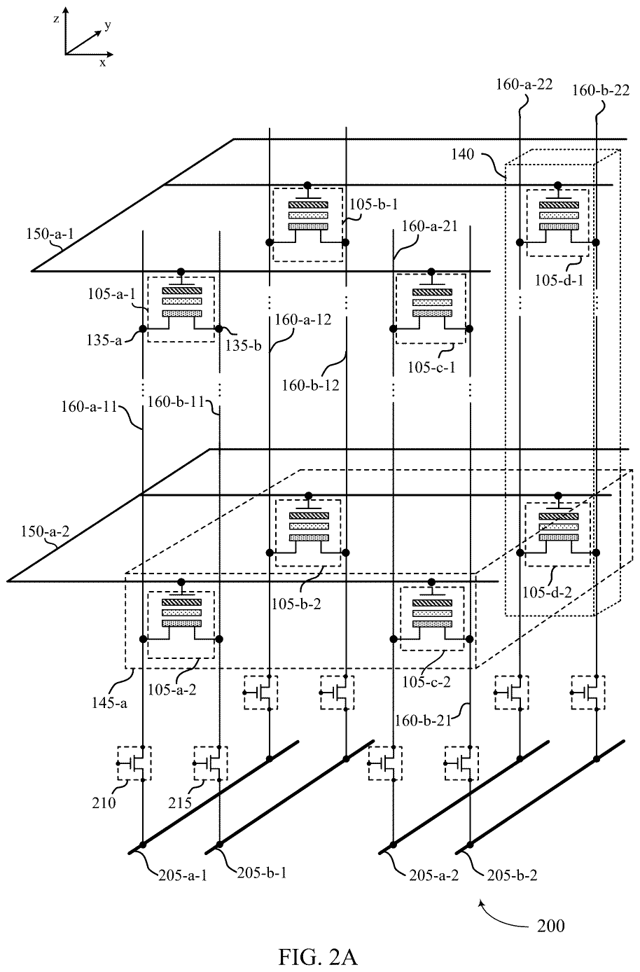

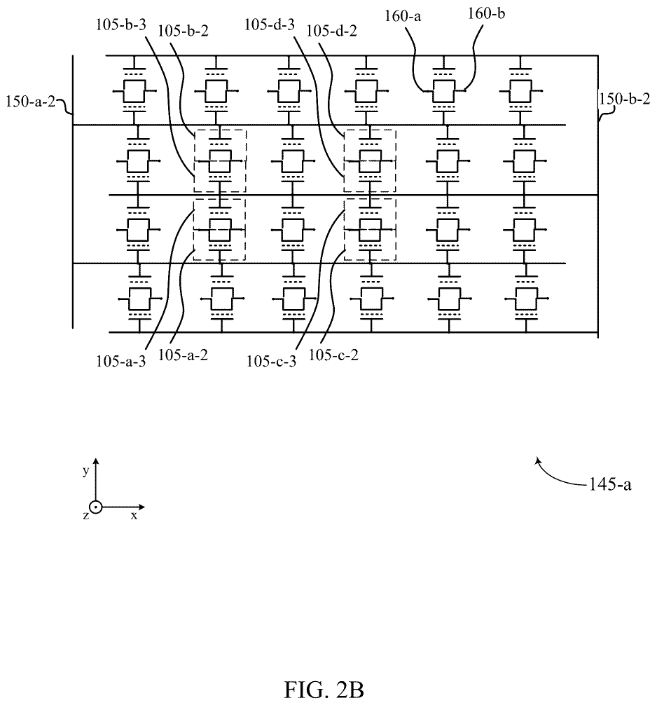

FIGS. 2A and 2B show examples of an architecture 200 (e.g., an array architecture, a memory array) that supports FeNOR memory architectures in accordance with examples as disclosed herein. The architecture 200 may be an example of portions of a memory device, such as a memory device 100. Although some elements of a set of elements (e.g., an array of elements) are included in FIGS. 2A and 2B, some elements may be omitted for the sake of visibility and clarity of the depicted elements. Moreover, although some elements included in FIGS. 2A and 2B are labeled with reference numbers, some other corresponding elements are not labeled, though they would be understood by a person having ordinary skill in the art to be the same as or similar to the labeled elements. Aspects of an architecture 200 may be described with reference to an x-direction, a y-direction, and a z-direction of the illustrated coordinate system.

The architecture 200 illustrates a 3D array of memory cells 105 (e.g., transistors 110), which may be connected in a 3D NOR configuration. For example, memory cells 105 may be arranged according to pillars 140 (e.g., columns, of memory cells 105) along the z-direction, each of which may include one or more (e.g., two) stacks of memory cells 105 along the z-direction. In some examples, each pillar 140 may be associated with a channel (e.g., a semiconductor channel, a semiconductor pillar) along the z-direction. A memory device 100 may include any quantity of one or more pillars 140 in accordance with examples as disclosed herein. In some implementations, each pillar 140 may include a first set of memory cells 105 at a first side of the pillar 140 (e.g., along the y-direction) and include a second set of memory cells 105 at a second side of the pillar 140 opposite the first side (e.g., along the y-direction). As illustrated, a first pillar 140 may include the memory cells 105-d-1 through 105-d-2 (e.g., positioned at a first side of the first pillar 140 along the y-direction) and, in some examples (not shown), may include a second set of memory cells 105 (e.g., positioned at a second side of the first pillar 140). Similarly, another pillar 140 may include the memory cells 105-a-1 through 105-a-2 (e.g., at a first side of the other pillar 140) and, in some examples (not shown), may include a second set of memory cells 105 (e.g., positioned at the second side of the other pillar 140), and so on.

Each pillar 140 may be associated with and positioned between a respective bit line 160-a (e.g., a conductive pillar) and a respective source line 160-b (e.g., a conductive pillar), and each memory cell 105 along a pillar 140 may be coupled with the same bit line 160-a and the same source line 160-b. For example, a same bit line 160-a may be coupled with the first node 135-a (e.g., a drain node) of each memory cell 105 (e.g., transistor 110) of a pillar 140, while a same source line 160-b may be coupled with the second node 135-b (e.g., a source node) of each memory cell 105 (e.g., transistor 110) of the pillar 140. As illustrated, the first nodes 135-a of the memory cells 105-a-1 through 105-a-2 may be coupled with the bit line 160-a-11, while the second nodes 135-b of the memory cells 105-a-1 through 105-a-2 may be coupled with the source line 160-b-11.

In some examples, the bit lines 160-a of one or more pillars 140 (e.g., in a group along the y-direction) may be coupled (e.g., selectively, via a transistor 210, via a pillar component 165) with a same bit line selector 205-a (e.g., an access line, a multiplexing line). For example, the bit line 160-a-11 coupled with memory cells 105-a of one pillar 140 and the bit line 160-a-12 coupled with memory cells 105-b of another pillar 140 may both be coupled (e.g., via a respective transistor 210) with the bit line selector 205-a-1. Likewise, the bit line 160-a-21 coupled with memory cells 105-c of one pillar 140 and the bit line 160-a-22 coupled with memory cells 105-d of another pillar 140 may both be coupled with the bit line selector 205-a-2. Although illustrated as being at a first end (e.g., bottom) of the architecture 200 (e.g., along the z-direction), it should be understood that such bit line selectors 205-a may be positioned at a second end (e.g., top) of the architecture 200 (e.g., along the z-direction). Transistors 210 may be coupled with activation lines (e.g., extending along the x-direction, coupled with gates of the transistors 210) and operated in accordance with various multiplexing and addressing techniques.

In some examples, the source lines 160-b of one or more pillars 140 (e.g., in a group along the y-direction) may be coupled (e.g., selectively, via a transistor 215, via a pillar component 165) with a same source line selector 205-b (e.g., an access line, a multiplexing line, a common source). For example, the source line 160-b-11 coupled with memory cells 105-a of one pillar 140 and the source line 160-b-12 coupled with memory cells 105-b of another pillar 140 may both be coupled (e.g., via a respective transistor 215) with the source line selector 205-a-1. Likewise, the source line 160-b-21 coupled with memory cells 105-c of one pillar 140 and the source line 160-b-22 coupled with memory cells 105-d of another pillar 140 may both be coupled with the source line selector 205-b-2. Although illustrated as being at a first end (e.g., bottom) of the architecture 200 along the z-direction, it should be understood that such source line selectors 205-b may be positioned at a second end (e.g., top) of the architecture 200 along the z-direction. Transistors 215 may be coupled with activation lines (e.g., extending along the x-direction, coupled with gates of the transistors 215) and operated in accordance with various multiplexing and addressing techniques.

In the example of architecture 200, the array of memory cells 105 may also be divided into a set of planes 145 arranged along the z-direction, including the plane 145-a associated with memory cells 105-a-2 through 105-d-2, and so on. In some examples, all memory cells 205 of a plane 145 may be activated by a same word line 150. In some other examples, subsets of memory cells 205 of a given plane 145 may be activated by a respective one of multiple word lines 150 associated with the given plane 145. For example, a plane 145 may be associated with word lines 150 configured in accordance with a comb structure (e.g., even and odd word lines 150). Such combed word lines 150 may be formed such that portions of the word line 150 (e.g., conductor portions, projections, tines) extend along the x-direction through gaps (e.g., alternating gaps) between pillars 140. For example, the architecture 200 may include two word lines 150 per plane 145 (e.g., according to odd word lines 150-a-1 and 150-a-2, with projections along the positive x-direction, and even word lines 150-b-1 (not shown) and 150-b-2 (e.g., as illustrated by the plane 145-a of FIG. 2B), with projections along the negative x-direction, where such word lines 150 of the same plane 145 may be described as being interleaved (e.g., with portions of an odd word line 150-a-2 projecting along the x-direction between portions of an even word line 150-b-2, and vice versa). In some examples, an even word line 150-b (e.g., of a plane 145) may be associated with a first memory cell 105 on a first side (e.g., along the y-direction) of a given pillar 140 and an odd word line 150-a (e.g., of the same plane 145) may be associated with a second memory cell 105 on a second side (e.g., along the y-direction, opposite the first memory cell 105) of the given pillar 140. Thus, in some examples, memory cells 105 of a given plane 145 may be addressed (e.g., selected, activated, multiplexed) in accordance with an even word line 150 or an odd word line 150.

FIG. 2B shows a top-down view of a plane 145-a that may be implemented in the architecture 200, illustrating a combed word line structure. As illustrated, the word line 150-a-2 may have portions that extend (e.g., into the array of memory cells 105) along the positive x-direction, and the word line 150-b-2 may have portions that extend along the negative x-direction. Accordingly, the memory cells 105-a-2, 105-b-2, 105-c-2, and 105-d-2 may be coupled with (e.g., activated by) the word line 150-a-2 (e.g., an odd word line), and the memory cells 105-a-3, 105-b-3, 105-c-3, and 105-d-3 (e.g., opposite the memory cells 105-a-2, 105-b-2, 105-c-2, and 105-d-2 along the y-direction) may be coupled with the word line 150-b-2 (e.g., an even word line).

To operate the architecture 200 (e.g., to perform a program operation, a read operation, or an erase operation on one or more memory cells 105 of a pillar 140), various voltages may be applied to one or more word lines 150 (e.g., to one or more gates of the transistors 110), to one or more bit lines 160-a (e.g., to first node 135-a or drain of one or more transistors 110), to one or more source lines 160-b (e.g., to the second node 135-b or source of the transistors 110), or any combination thereof.

In some cases, as part of a program operation for a target memory cell 105, a polarization (e.g., a dipole polarization, a stored electric field) may be induced by applying an electric field (e.g., a coercive field, a saturation field, a polarizing field) across a ferroelectric portion 125 of the target memory cell 105. Additionally, in some examples, an electric charge may be induced (e.g., injected, by way of charge transfer, by way of electron transfer) based on applying the electric field (e.g., across the memory cell), in which case a charge stored in a charge-trapping material may accompany a polarization to store a logic state at the memory cell 105. In some cases, respective voltages may be applied to word line(s) 150, bit line(s) 160-a, and source line(s) 160-b, such that a gate 115 of the target memory cell 105 is at a higher voltage than the first node 135-a and the second node 135-b of the target memory cell 105 (e.g., a relatively positive voltage may be applied to the word line, to store a “PROGRAM” state, to store a cell state 190-a). This may cause the electric field across features of the memory cell 105 (e.g., between the gate 115 and channel portion 130) such that a first polarization is induced into the ferroelectric portion 125 of the target memory cell 105, a positive charge is injected into a portion of the target memory cell 105, or both.

In such examples (e.g., program operation), the first polarization in the ferroelectric portion 125 may create a first dipole, where a concentration (e.g., a localization) of positive charges may be stored at a first side of the ferroelectric portion 125 and a concentration (e.g., a localization) of negative charges may be stored at a second side of the ferroelectric portion 125 opposite the first side. In such examples, the first side of the ferroelectric portion 125 may be in contact with or otherwise toward the channel portion 130 of the target memory cell 105, while the second side of the ferroelectric portion 125 may be in contact with the channel interlayer portion of the target memory cell 105 or otherwise toward a gate 115.

In some cases, as part of an erase operation for a memory cell 105 (e.g., to store an “ERASE” state, to store a cell state 190-b), the polarization of charge in the ferroelectric portion 125 of a memory cell may be changed (e.g., reversed). Additionally, in some examples, a charge stored in a portion of the memory cell 105 may be reversed as part of the erase operation. In some cases, respective voltages may be applied to word line(s) 150, bit line(s) 160-a, and source line(s) 160-b, such that a gate 115 of the target memory cell 105 is at a lower voltage than the first node 135-a and the second node 135-b of the target memory cell 105 (e.g., a relatively negative voltage may be applied to the word line). This may cause an electric field across the features of the memory cell 105 (e.g., between the gate 115 and the channel portion 130), such that a second polarization is induced into the ferroelectric portion 125 of the target memory cell 105, a negative charge is injected into a portion of the target memory cell 105, or both.

In such examples (e.g., erase operation), the second polarization of charge in the ferroelectric portion 125 may create a second dipole, where a concentration of negative charges may be stored at the first side of the ferroelectric portion 125 and a concentration of positive charges may be stored at the second side of the ferroelectric portion 125 opposite the first side. In such examples, the first side of the ferroelectric portion 125 may be in contact with or otherwise toward the channel portion 130 of the target memory cell 105, while the second side of the ferroelectric portion 125 may be in contact with the channel interlayer portion of the target memory cell 105 or otherwise toward a gate 115.

In some cases, as part of a read operation for a target memory cell 105, a positive voltage may be applied to the corresponding bit line 160-a, while the corresponding source line 160-b may be grounded or otherwise biased with a voltage lower than the voltage applied to the bit line 160-a. Additionally, the corresponding word line 150 may be biased with a positive voltage (e.g., to potentially activate the memory cell 105, based on a level of charge stored in the ferroelectric portion 125), which may be greater than the positive voltage applied to the corresponding bit line 160-a but may be less than a voltage applied during programming of the target memory cell 105. In this way, by biasing the corresponding bit line 160-a, the source line 160-b, and the word line 150, the logic value of the target memory cell 105 may be read (e.g., evaluating whether the target memory cell 105 stores a cell state 190-a or a cell state 190-b).

A signal on the bit line 160-a-11 corresponding to the memory cell 105-a-1 (e.g., an amount of current, such as a current below or above a threshold) may be sensed (e.g., by a sense component 170) and may indicate whether the memory cell 105-a-1 became conductive (e.g., if written to a cell state 190-a) or remained non-conductive (e.g., if written with a cell state 190-b) in response to the application of the various voltages. The sensed signal thus may be indicative of whether the memory cell 105 was in an erased state (e.g., an “ERASE” state, storing a logic 1) or a programmed state (e.g., a “PROGRAM” state, storing a logic 0), or some other state (e.g., of a multiple-level configuration of the memory cell 105-a-1). That is, the sense component 170 may determine a logic state of the memory cell 105-a-1 based on the signal generated on the bit line 160-a-11 according to biasing the word line 150-a-1 with the second voltage, biasing the source line 160-b-11 with the ground voltage, and on biasing the bit line 160-a-11 with the third voltage.

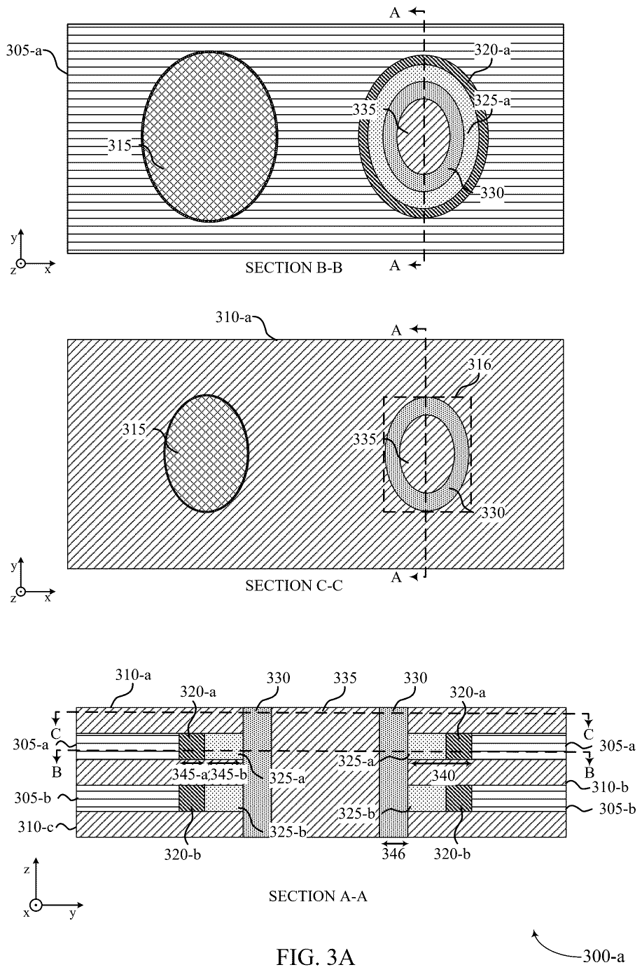

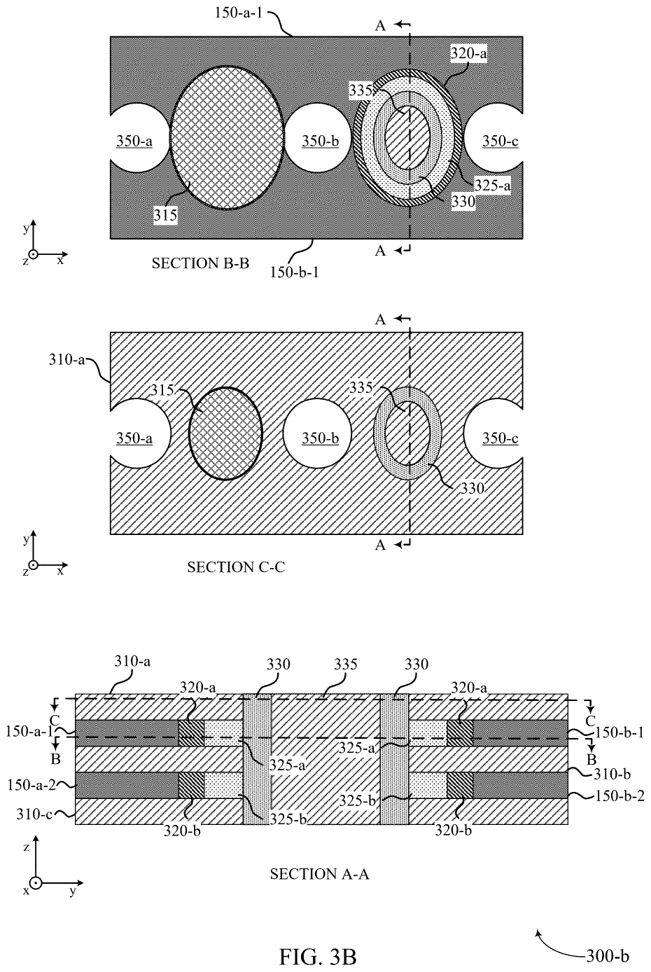

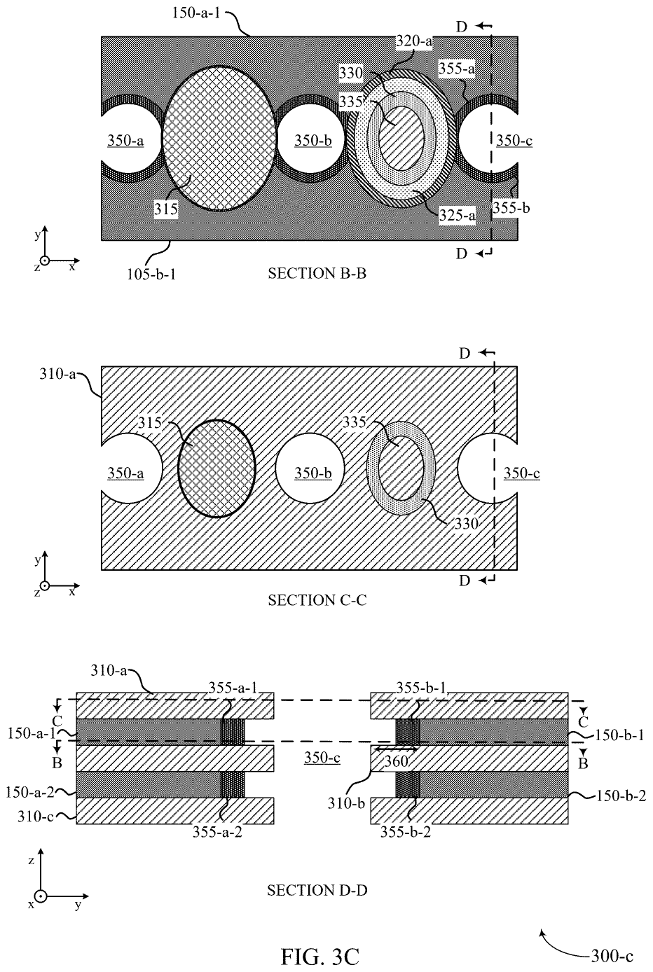

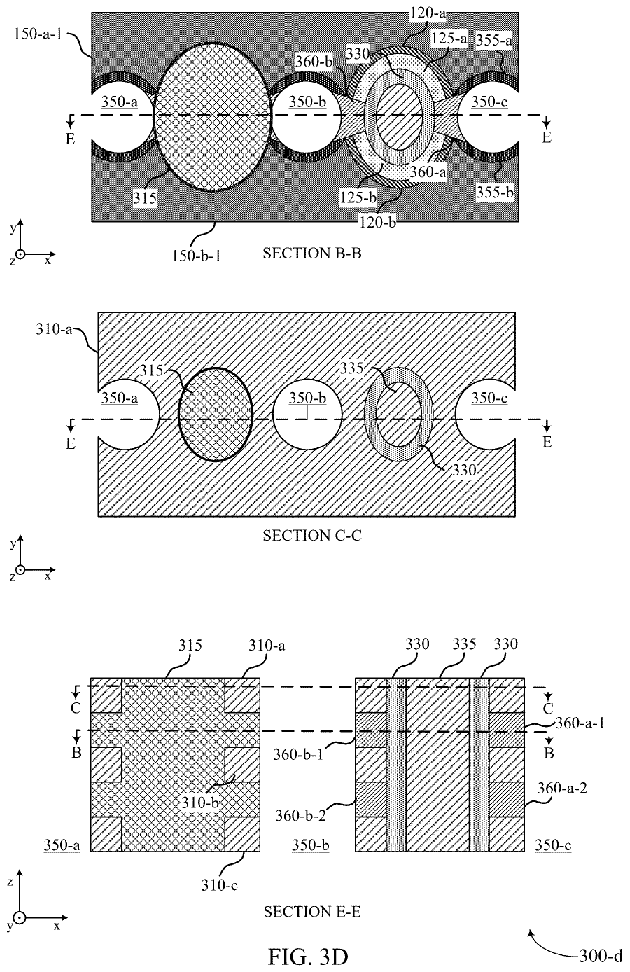

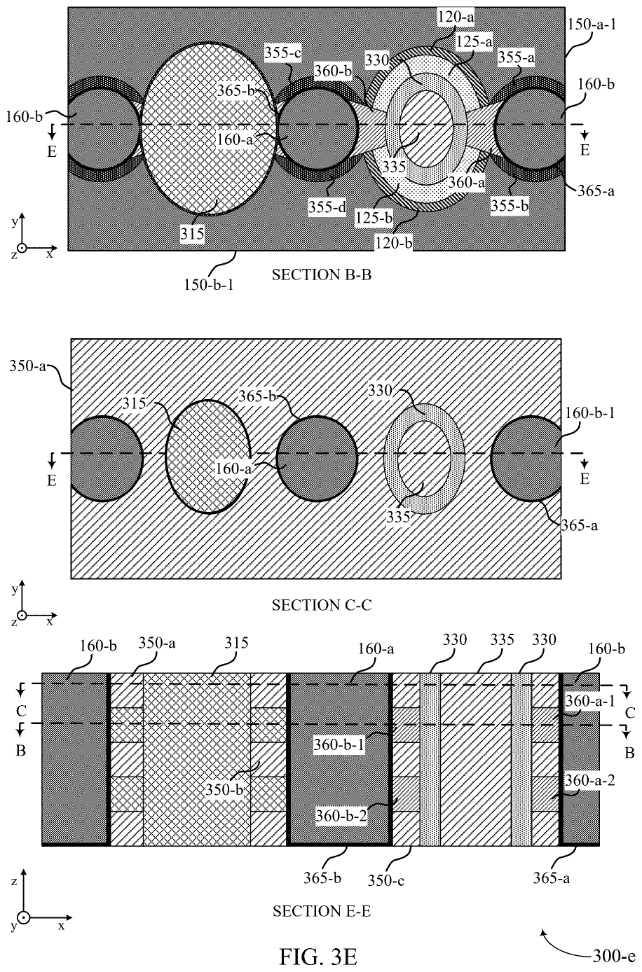

FIGS. 3A, 3B, 3C, 3D, and 3E show examples of fabrication operations that support FeNOR architectures in accordance with examples as disclosed herein. For example, FIGS. 3A through 3E may illustrate a sequence of operations for fabricating aspects of an architecture 300 (e.g., as a portion of a semiconductor wafer), which may implement aspects of a memory device 100, or an architecture 200, or another implementation of a semiconductor component (e.g., a memory component). In some examples, the architecture 300 may be a portion of memory die, or a wafer that includes multiple memory dies, such as NOR die (e.g., a 3D-NOR die, a die having an arrangement of NOR memory cells in a three-dimensional array). Although some elements included in FIGS. 3A through 3E are labeled with reference numbers, some other corresponding elements are not labeled, though they would be understood by a person having ordinary skill in the art to be the same as or similar to the labeled elements.

Each of FIGS. 3A through 3E may illustrate aspects of the architecture 300 after different subsets of the fabrication operations for forming the architecture 300 (e.g., illustrated as an architecture 300-a after a first set of one or more fabrication operations, as an architecture 300-b after a second set of one or more fabrication operations, and so on). Each view of FIGS. 3A through 3E may be described with reference to an x-direction (e.g., a first direction over a substrate, not shown), a y-direction (e.g., a second direction over the substrate), and a z-direction (e.g., a direction from the substrate) of the illustrated coordinate system, which may correspond to the respective directions described with reference to the architecture 200. Aspects of the architecture 300 may be illustrated in accordance with cross-sectional section views A-A (e.g., in a yz-plane), B-B (e.g., in an xy-plane), C-C (e.g., in an xy plane), D-D (e.g., in a yz-plane), and E-E (e.g., in an xz-plane) to show embedded features of the architecture 300.

FIG. 3A shows the architecture 300 (e.g., as an architecture 300-a) after a first set of one or more fabrication operations. The techniques described in the context of FIG. 3A may be used to form one or more pillars and associated components of the architecture 300.

For example, a stack of layers (e.g., layers in a respective xy-plane) may be formed over a substrate, and the stack of layers may include nitride layers 305 and oxide layers 310 that are alternating along the z-direction. As illustrated in the cross-sectional view A-A, the stack of layers may be formed to include an oxide layers 310-a, 310-b, and 310-c, with a nitride layer 305-a between the oxide layers 310-a and 310-b and a nitride layer 305-b between the oxide layers 310-b and 310-c. An architecture 300 may include any quantity of nitride layers 305 and oxide layers 310, and a quantity of nitride layers 305 may, in some examples, correspond to a quantity of memory cells 105 in pillars 140 of a memory device 100. After forming the stack of layers, multiple cavities may be formed through the stack of layers along the z-direction (e.g., terminating at or above the substrate), which may be formed using an etching procedure (e.g., a dry etch, a directional etch, a laser material removal operation, among other examples). In such examples, the cavities may be formed in an elliptical shape (e.g., as a cross-section in an xy-plane), as illustrated in FIG. 3A. In some other examples, the cavities may be formed in a circular shape, a square shape, a rectangular shape, a rounded rectangular shape, or any combination thereof.

In some examples, one or more voids may be formed in each nitride layer 305 of the stack of layers. For example, a procedure (e.g., nitride recess procedure, a wet etch operation) may be performed through each of the cavities (e.g., cavities associated with active pillars) to recess (e.g., remove) a respective portion 340 of nitride from each nitride layer 305 (e.g., in directions of an xy-plane from a sidewall of the cavities), thereby forming the one or more voids into each nitride layer 305 (e.g., between oxide layers 310). As shown in the cross-sectional view A-A, a respective portion 340 of the nitride layers 305-a and 305-b may be recessed (e.g., from a sidewall of cavities formed through the stack of layers).

After forming the multiple cavities and the one or more voids in each nitride layer 305, a first dielectric material (e.g., aluminum oxide (AIOx), hafnium oxide (HfOx), silicon oxycarbide (SIOC), silicon carbonitride (SiCN), silicon dioxide, or a combination thereof) may be formed into each cavity. Accordingly, a subset of the cavities (e.g., cavities associated with the active pillars) chosen to include memory cells 105 may undergo a dielectric exhume and cell integration process, and a remaining subset of cavities may remain protected by a mask and not open for the exhume operation. That is, based on forming the multiple cavities and the one or more voids in each nitride layer 305, the first dielectric material may be formed into each cavity and into the one or more voids of each nitride layer 305, thereby forming the dielectric pillar 315 and a second pillar 316, and the dielectric pillar 315 illustrated in FIG. 3A may be selected as an inactive pillar, whereas the second pillar 316 may be selected as an active pillar. Accordingly, the first dielectric material deposited into the cavities associated with an active pillar may be exhumed (e.g., removed), thereby re-exposing the corresponding cavity. Additionally, the first dielectric material deposited into the one or more voids of the nitride layers 305 may also be exhumed, thereby re-exposing the one or more voids of the nitride layers 305.

In some examples, after exhuming the first dielectric material, multiple portions 320 of a second dielectric material (e.g., interlayer portions, a same dielectric material as the first dielectric material, a different dielectric material from the first dielectric material) may be formed into portions 345-a of the multiple voids in the nitride layers 305. For example, the second dielectric material (e.g., interlayer) may be formed into each exposed cavity and into the respective voids of the nitride layers 305. Subsequently, a portion of the second dielectric material may be exhumed (e.g., recessed, between oxide layers 310) to reform each cavity and form a portion 345-b of each void of the nitride layers 305. By doing so, a respective portion 320 may be formed in a respective void of the nitride layers 305 and be positioned (e.g., recessed or confined) between each oxide layer 310 and in contact with each nitride layer 305. In some other examples, after exhuming the first dielectric material, the second dielectric material may be selectively deposited into the portions 345-a (e.g., into nitride layers 305, between oxide layers 310), thereby forming the portions 320 of the second dielectric material (e.g., without a recession step). For example, as shown in the cross-sectional view A-A, a portion 320-a of the second dielectric material may be formed into the nitride layer 305-a, and a portion 320-b of the second dielectric material may be formed into the nitride layer 305-b (e.g., each forming a ring of the second dielectric material around the previously-formed cavities).

After forming the portions 320, multiple portions 325 of a storage material (e.g., one or more materials, a ferroelectric material, a combination of a ferroelectric material and a charge-trapping material) may be formed into the portions 345-b of the multiple voids in the nitride layers 305. For example, a ferroelectric material may be formed into each exposed cavity and into the portions 345-b of each void of the nitride layers 305 (e.g., between oxide layers 310). Subsequently, a portion of the ferroelectric material may be exhumed to reform each cavity. By doing so, a respective portion 325 may be formed in a respective void of the nitride layers 305 and be positioned (e.g., recessed into, confined) between each oxide layer 310 and in contact with a respective portion 320 of the second dielectric material. In some other examples, after forming the portions 320, the ferroelectric material may be selectively deposited into the portion 345-b, thereby forming the portions 325 of the storage material. For example, as shown in the cross-sectional view A-A, a portion 325-a of the storage material may be formed into the nitride layer 305-a, and a portion 325-b of the storage material may be formed into the nitride layer 305-b (e.g., each forming a ring of the storage material within a ring of the second dielectric material).

After forming the portions 325, a first semiconductor material 330 (e.g., p-type doped polysilicon) may be formed (e.g., deposited) along a sidewall of each cavity according to a selected thickness 346, and the first semiconductor material 330 may be in contact with each portion 325 of the storage material. Due to forming the first semiconductor material 330 along the sidewall of each cavity, a second cavity may be formed. In some examples, an etching procedure may be performed to adjust (e.g., decrease) the thickness 346 of the first semiconductor material 330. After forming the first semiconductor material 330, a respective pillar 335 may be formed into each second cavity. For example, an oxide material, which may be the same oxide material as the oxide layers 310 or a different oxide material as the oxide layers 310, may be formed into the second cavities to form the pillars 335. As shown in the cross-sectional view A-A, the first semiconductor material 330 may extend along a length of the pillar 335 along the z-direction and be between the pillar 335 and the portions 325 of the storage material.

FIG. 3B shows the architecture 300 (e.g., as an architecture 300-b) after a second set of one or more fabrication operations. The techniques described in the context of FIG. 3B may be used to form word lines 150.

For example, multiple cavities 350 (e.g., cavities 350-a, 350-b, and 350-c) may be formed through the stack of layers along the z-direction (e.g., terminating at or above the substrate). In such examples, each cavity 350 may be formed adjacent to a respective pillar 335 or dielectric pillar 315. For example, the cavity 350-b may be formed on a first side of the pillar 335 along the x-direction, and the cavity 350-c may be formed on a second side of the pillar 335 along the x-direction. As a result of forming the cavities 350, the nitride layers 305 may be divided into a comb structure, with multiple first nitride layers 305 at a third side of the pillar 335 along the y-direction and multiple second nitride layers 305 at a fourth side of the pillar 335 along the y-direction. That is, by forming the cavities 350, each nitride layer 305 originally formed in alternating layers with oxide layers 310 may divided into a respective first nitride layer 305 and a respective second nitride layer 305.

Subsequently, multiple word lines 150-a (e.g., odd word lines, formed using tungsten, molybdenum, or ruthenium) may be formed in place of the multiple first nitride layers 305 and multiple word lines 150-b (e.g., even word lines, formed using tungsten, molybdenum, or ruthenium) may be formed in place of the multiple second nitride layers 305. For example, after forming the cavities 350, multiple first voids may be formed by exhuming, through the cavities 350, the nitride material from each of the multiple first nitride layers 305. Similarly, multiple second voids may be formed by exhuming, through the cavities 350, the nitride material from each of the multiple second nitride layers 305. As such, a respective word line 150-a of the multiple word lines 150-a may be formed into a respective first void of the multiple first voids, and a respective word line 150-b of the multiple word lines 150-b may be formed into a respective second void of the multiple second voids (e.g., by forming one or more conductive materials in the voids). Accordingly, as shown in the cross-sectional view A-A, the nitride layer 305-a may be replaced by the word line 150-a-1 and the word line 150-b-1, and the nitride layer 305-b may be replaced by the word line 150-a-2 and the word line 150-b-2.

FIG. 3C shows the architecture 300 (e.g., as an architecture 300-c) after a third set of one or more fabrication operations. The techniques described in the context of FIG. 3C may be used to form portions 355 of a third dielectric material (e.g., AIOx, HfOx, SIOC, SiCN, silicon dioxide, or a combination thereof).

To form the portions 355 of the third dielectric material, a procedure (e.g., metal recession procedure) may be performed to recess (e.g., remove) a respective portion 360 of metal from each word line 150, thereby forming multiple voids into each word line 150 (e.g., between oxide layers 310). For example, a respective first void may be formed into each word line 150-a through a first side of a respective cavity 350, and a respective second void may be formed into each word line 150-b through a second side of a respective cavity 350 opposite the first side along the y-direction. For example, as shown in the cross-sectional view B-B, a portion 360 of the word lines 150-a-1, 150-a-2, 150-b-1, and 150-b-2 may be recessed between oxide layers 310 (e.g., along directions in respective xy-planes).

After forming the voids, the third dielectric material may be formed (e.g., deposited) into the cavities 350 and into the voids. After forming the third dielectric material into the cavities 350, a portion of the third dielectric material may be removed (e.g., selectively etched, recessed between oxide layers 310) from the cavities 350, thereby forming the portions 355 into each void of the word lines 150. For example, a respective portion 355-a (e.g., first portion) of the third dielectric material may be formed into each first void, and a respective portion 355-b may be formed into each second void. In some examples, as illustrated, the portions 355 of the third dielectric material may be formed in a portion of the voids at each word line deck (e.g., with a recession into the voids). Alternatively, the portions 355 of the third dielectric material may be formed to fill each void in the word line deck. That is, the portions 355 of the third dielectric material may be formed to fill the portion 360 removed from each word line 150 (e.g., without a recession). Such removal of the portion of the third dielectric material may also expose each portion 320-a of the second dielectric material (not shown).

Accordingly, as shown in the cross-sectional view A-A, the portion 355-a-1 may be positioned between the oxide layers 310 (e.g., confined within a single word line deck) and separate the word line 150-a-1 from the cavity 350-c. Similarly, the portion 355-b-1 may be positioned between the oxide layers 310 (e.g., confined within a single word line deck) and separate the word line 150-b-1 from the cavity 350-c.

FIG. 3D shows the architecture 300 (e.g., as an architecture 300-d) after a fourth set of one or more fabrication operations. The techniques described in the context of FIG. 3D may be used to form portions 360 of a second semiconductor material (e.g., n-type doped polysilicon).

For example, multiple portions 360-a of the second semiconductor material may be formed, and each portion 360-a of the second semiconductor material may be formed through a respective portion 320 of the second dielectric material and through a respective portion 325 of the storage material on the second side of the pillar 335 (e.g., along the x-direction). Additionally, multiple portions 360-b of the second semiconductor material may be formed, and each portion 360-b may be formed through a respective portion 320 of the second dielectric material and through a respective portion 325 of the storage material on the first side of the pillar 335 (e.g., along the x-direction, opposite the second side).

As shown in the cross-sectional view B-B, each of the portions 360-a may be formed, and each portion 360-a may be positioned between each oxide layers 310 and correspond to a respective word line deck. As an illustrative example, a position (e.g., along the z-direction) of the portions 360-a-1 and 360-b-1 may correspond to (e.g., overlap along the z-direction, have an overlapping thickness with) a position of the word lines 150-a-1 and 150-b-1, and a position of the portions 360-a-2 and 360-b-2 may correspond to a position of the word lines 150-a-2 and 150-b-2. By forming the portions 360-a and 360-b, the portions 320 of the second dielectric material may be divided into dielectric portions 120-a at the third side of the pillar 335 (e.g., along the y-direction) and dielectric portions 120-b at the fourth side of the pillar 335 (e.g., along the y-direction, opposite the third side). Similarly, by forming the portions 360-a and 360-b, the portions 325 of the storage material (e.g., a ferroelectric material, a charge-trapping material, or combination thereof) may be divided into portions 125-a at the third side of the pillar 335 and portions 125-b at the fourth side of the pillar 335.

To form the portions 360-a along the second side of the pillar 335, a respective first void may be formed (e.g., via a wet etch operation) through each portion 320 and each portion 325 to expose the first semiconductor material 330 along the second side of the pillar. Subsequently, the second semiconductor material may be formed in the cavity 350-c and into each respective first void. Subsequently, a portion of the second semiconductor material may be selectively removed (e.g., recessed) to reform the cavity 350-c, thereby forming each portion 360-a along the second side of the pillar 335.

Similarly, to form the portions 360-b along the first side of the pillar 335, a respective second void may be formed through each portion 320 and each portion 325 to expose the first semiconductor material 330 along the first side of the pillar. Subsequently, the second semiconductor material may also be formed in the cavity 350-b and into each respective second void. Subsequently, a portion of the second semiconductor material may be selectively removed to reform the cavity 350-b, thereby forming each portion 360-b along the first side of the pillar 335.

FIG. 3E shows the architecture 300 (e.g., as an architecture 300-e) after a fifth set of one or more fabrication operations. The techniques described in the context of FIG. 3E may be used to form access lines 160, such as a bit line 160-a or a source line 160-b.

For example, access lines 160 may be formed in the cavities 350 (e.g., by forming one or more conductor materials in the cavities 350), and the access lines may extend along the z-direction of the stack of layers to the substrate. To form the access lines 160, a barrier material 365 (e.g., a first conductor material, titanium silicon (TiSi), tungsten nitride (WN), titanium nitride (TiN)) may be formed along a sidewall of each cavity 350. For example, the barrier material 365-a may be formed along the sidewall of the cavity 350-c, and the barrier material 365-b may be formed along the side wall of the cavity 350-b. After forming the barrier materials 365, a core conductor material (e.g., a second conductor material, tungsten, molybdenum) may be deposited into the cavities 350, thereby forming the access lines 160.

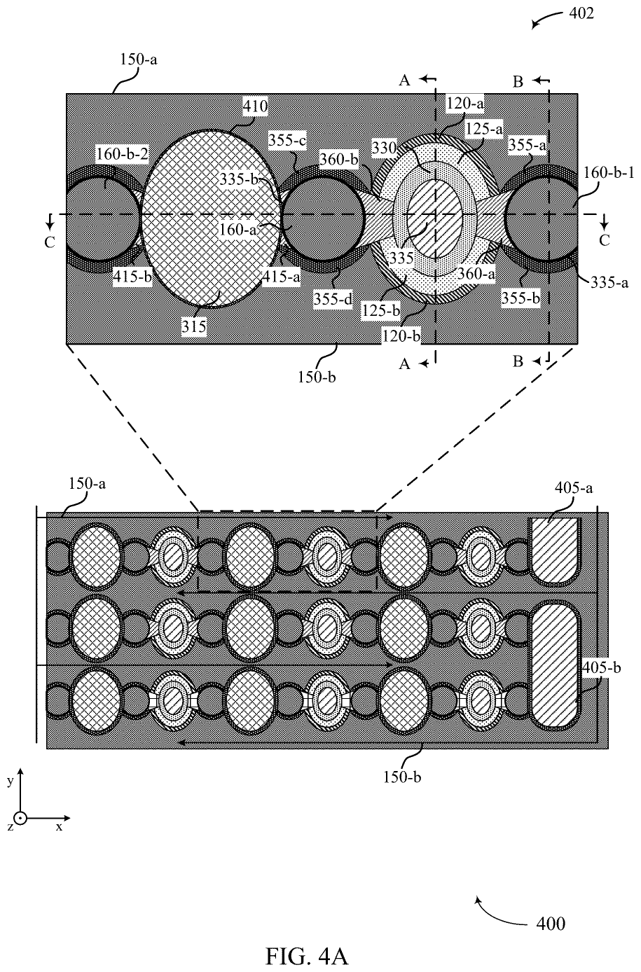

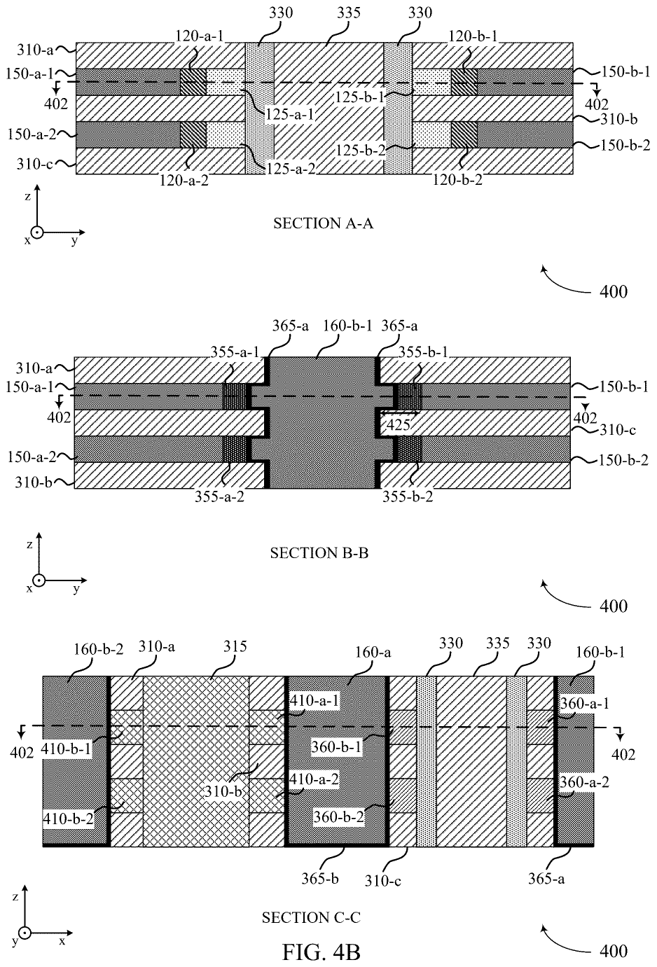

FIGS. 4A and 4B show an architecture 400 (e.g., a material architecture, a memory array) that supports FeNOR memory architectures in accordance with examples as disclosed herein. Aspects of the architecture 400 may implement, or be implemented by, aspects of a memory device 100, an architecture 200, an architecture 300, or a combination thereof. For example, the architecture 400 may include one or more memory cells 105 configured in a pier and pillar architecture, as described herein. Additionally, the architecture 400 may be formed as a result of the operations to form the architecture 300, as described with reference to FIGS. 3A through 3E.

The architecture 400 may include multiple pillars 335 formed into a stack of materials, which may include an alternation (e.g., along the z-direction) between word line decks (e.g., word lines 150) and oxide layers 310, such that each pillar 335 may be positioned between a respective source line 160-b (e.g., a conductive pillar) and a respective bit line 160-a (e.g., another conductive pillar pillar). For example, a pillar 335 may be positioned between the bit line 160-a and the source line 160-b-1. Each pillar 335 may include a core dielectric material (e.g., silicon dioxide) that extends through the stack of materials along the z-direction, and a first semiconductor material 330 (e.g., one or more channel portions 130) around the core dielectric material that extends along the length of the pillar 335 along the z-direction.

The architecture 400 may include multiple word line decks, and each word line deck may include a single odd word line 150-a (e.g., a first conductor) and a single even word line 150-b (e.g., a second conductor, interleaved with the single odd word line 150-a). Such even and odd word lines 150 may be separated (e.g., isolated, along the x-direction) via dielectric structures 405-a and 405-b.

As illustrated in the view 402, a respective combination of pillars 335, bit lines 160-a, and source lines 160-b may be separated (e.g., isolated, along the x-direction) via a dielectric pillar 315, such that each bit line 160-a and each source line 160-b is coupled with a single pillar 335. For example, the dielectric pillar 315 may separate (e.g., isolate) the bit line 160-a from the source line 160-b-2.

The first semiconductor material 330 of each pillar 335 may be coupled with (e.g., in contact with) one or more first ferroelectric portions 125-a at a first side of the pillar 335, including examples in which multiple first ferroelectric portions 125-a are distributed along the pillar 335 (e.g., along the z-direction) and are recessed (e.g., confined, positioned) at each word line deck (e.g., associated with a respective word line 150-a). Each first ferroelectric portion 125-a may be coupled with a respective dielectric portion 120-a (e.g., a word line interlayer, a gate dielectric) that is positioned between a respective word line 150-a and a respective first ferroelectric portion 125-a. In such examples, a combination of a dielectric portion 120-a, a first ferroelectric portion 125-a, and a portion of the first semiconductor material 330 (e.g., of a channel portion 130) may be associated with a memory cell 105. As such, multiple first memory cells 105 may be positioned between a respective word line 150-a and the pillar 335 at the first side of the pillar 335.

Similarly, the first semiconductor material 330 of each pillar 335 may be coupled with (e.g., in contact with) one or more second ferroelectric portions 125-b at a second side of the pillar 335, including examples in which multiple second ferroelectric portions 125-b are distributed along the pillar 335, and are recessed at each word line deck (e.g., may be associated with a respective word line 150-b). Each second ferroelectric portion 125-b may be coupled with a respective dielectric portion 120-b (e.g., word line interlayer, a gate dielectric) that is positioned between a respective word line 150-b and a respective second ferroelectric portion 125-b. In such examples, a combination of a dielectric portion 120-b, a second ferroelectric portion 125-b, and a portion of the first semiconductor material 330 may be associated with a memory cell 105. As such, multiple second memory cells 105 may also be positioned between a respective word line 150-b and the pillar 335 at a second side of the pillar 335.

In some implementations, each of the bit lines 160-a may include a core conductor material, which may be in contact with an inner surface of a barrier material 335-b. To avoid shorts between the bit lines 160-a and the word lines 150, the architecture 400 may include multiple portions 355-c of a dielectric material at a first end (e.g., along the y-direction) of the bit line 160-a that each separate the first end of the bit line 160-a from a word line 150 (e.g., even or odd word line). Similarly, the architecture 400 may include multiple portions 355-d at a second end of the bit line 160-a that each separate the bit line 160-a from a word line 150 (e.g., even or odd word line). In some examples, the portions 355-c and 355-d may be recessed at each word line deck (e.g., as illustrated in the cross-sectional view B-B of FIG. 4B). In some other examples, the dielectric material may extend continuously through the architecture 400 along the z-direction.

Similarly, each of the source lines 160-b may include a core conductor material, which may be coupled with an inner surface of a barrier material 335-a. To avoid shorts between the source lines 160-b and the word lines 150, the architecture 400 may include multiple portions 355-a of the dielectric material at a first end (in the y-direction) of the source line 160-b that each separate the first end of the source line 160-b from the word line 150 (e.g., even or odd word line). Similarly, the architecture 400 may include multiple portions 355-b at a second end of source line 160-b that each separate the source line 160-b from the word line 150 (e.g., even or odd word line). In some examples, the portions 355-a and 355-b may be recessed at each word line deck (e.g., as illustrated in the cross-sectional view B-B of FIG. 4B). In some other examples, the dielectric material may extend continuously through the architecture 400 along the z-direction. Additionally, in some examples, the dielectric pillars 315 may be surrounded, contiguously, by a portion 410 of the dielectric material (e.g., AIOx, HfOx, SIOC, SiCN, or a combination thereof).

Each source line 160-b may be coupled with the first semiconductor material 330, the multiple ferroelectric portions 125, and the dielectric portions 120 of the pillars 335 via respective first portions 360-a of a second semiconductor material. Similarly, each bit line 160-a may be coupled with the first semiconductor material 330, the multiple ferroelectric portions 125, and the dielectric portions 120 of the pillars 335 via respective second portions 360-b of a second semiconductor material.

In some examples, each first portion 360-a and second portion 360-b may be recessed (e.g., confined) in a respective word line deck. Accordingly, a respective first portion 360-a, a respective second portion 360-b, and a respective first portion of the first semiconductor material 330 (e.g., aligned with the respective word line deck, on one side of a pillar 335) may form a first channel between the bit line 160-a and the source line 160-b at a first side of the pillar 335, which may be utilized to store (e.g., write), read, or erase a polarization of charge of the respective first ferroelectric portion 125-a. Similarly, a respective first portion 360-a, a respective second portion 360-b, and a respective second portion of the first semiconductor material 330 (e.g., aligned with the respective word line deck, on another side of the pillar 335) may form a second channel between the bit line 160-a and the source line 160-b at a second side of the pillar 335, which may be utilized to store (e.g., write), read, or erase a polarization of charge of the respective second ferroelectric portion 125-b.

In some examples, the source lines 160-b and the bit lines 160-a may be in contact with the dielectric pillars 315 via respective portions 405 of dielectric material. For example, the bit line 160-a may be in contact the dielectric pillar 315 via the portions 415-a, and the source line 160-b-2 may be in contact with the dielectric pillar 315 via the portions 415-b.

FIG. 4B shows cross-sectional views of the architecture 400 (e.g., of the view 402). As illustrated in cross-sectional view A-A, each ferroelectric portion 125 and dielectric portion 120 may be recessed into a respective word line and be between two respective oxide layers 310. For example, the first ferroelectric portion 125-a-1 and the dielectric portion 120-a-1 may be recessed into word line 150-a-1 and between the oxide layer 310-a and the oxide layer 310-b, and the first ferroelectric portion 125-a-2 and the dielectric portion 120-a-2 may be recessed into the word line 150-a-2 and between the oxide layer 310-b and the oxide layer 310-c. Similarly, the second ferroelectric portion 125-b-1 and the dielectric portion 120-b-1 may be recessed into word line 150-b-1 and between the oxide layer 310-a and the oxide layer 310-b, and the second ferroelectric portion 125-b-2 and the dielectric portion 120-b-2 may be recessed into the word line 150-b-2 and between the oxide layer 310-b and the oxide layer 310-c. Although illustrated as extending through the stack of materials, in some examples, the first semiconductor material 330 may be recessed at each word line deck, such that each ferroelectric portion 125 may be coupled with a respective portion of the first semiconductor material 330.

Accordingly, to access a memory cell 105 that includes the dielectric portion 120-a-1, the first ferroelectric portion 125-a-1, a voltage may be applied to the word line 150-a-1, which may modulate conductivity of a channel, between the bit line 160-a and the source line 160-b-1, via the dielectric portion 120-a-1, the first ferroelectric portion 125-a-1, and the first semiconductor material 330, as described herein with reference to FIGS. 2A and 2B. Similarly, to access a memory cell 105 that includes the dielectric portion 120-b-1, the first ferroelectric portion 125-b-1, a voltage may be applied to the word line 150-b-1, which may modulate conductivity of a channel, between the bit line 160-a and the source line 160-b-1, via the dielectric portion 120-b-1, the first ferroelectric portion 125-b-1, and the first semiconductor material 330, as described herein with reference to FIGS. 2A and 2B.

As illustrated in the cross-sectional view B-B, the source line 160-b-1 may extend, along the z-direction, through the stack of layers, as described herein with reference to FIGS. 3A through 3E. In such examples, the portions 355 may be recessed at each word line deck. For example, the portion 355-a-1 may be recessed into the word line 150-a-1 and be between the oxide layer 310-a and the oxide layer 310-b, and the portion 355-a-2 may be recessed into the word line 150-a-2 and be between the oxide layer 310-b and the oxide layer 310-c. Similarly, the portion 355-b-1 may be recessed into the word line 150-b-1 and be between the oxide layer 310-a and the oxide layer 310-b, and the portion 355-b-2 may be recessed into the word line 150-b-2 and be between the oxide layer 310-b and the oxide layer 310-c. In some other examples, the dielectric material may extend along the source line 160-b-1 (e.g., along the z-direction). In some examples, as described herein with reference to FIG. 3C, the portions 355 may extend a length 425 along the y-direction at each word line deck (e.g., fill the portions 360).

As illustrated in cross-sectional view C-C, the bit line 160-a and the source line 160-b-1 may be coupled with first semiconductor material 330 via respective portions 360 of the second semiconductor material, and each respective portion 360 of the semiconductive material may be recessed at a respective word line deck. For example, the source line 160-b-1 may be coupled with the first semiconductor material 330 via the first portion 360-a-1 (e.g., corresponding to the word line deck including the word line 150-a-1 and the word line 150-b-1) and the second portion 360-a-2 (e.g., corresponding to the word line deck including the word line 150-a-2 and the word line 150-b-2). Similarly, the bit line 160-a may be coupled with the first semiconductor material 330 via the second portion 360-b-1 (e.g., corresponding to the word line deck including the word line 150-a-1 and the word line 150-b-1) and the second portion 360-b-2 (e.g., corresponding to the word line deck including the word line 150-a-2 and the word line 150-b-2).

In some examples, the bit line 160-a and the source lines 160-b may be in contact with the dielectric pillar 315 via respective portions 415 of the dielectric material, which may provide additional support for the bit line 160-a and the source lines 160-b. For example, the bit line 160-a may be in contact with the dielectric pillar 315 via the portion 415-a-1 and the portion 415-a-2, and the source line 160-b-2 may be in contact with the dielectric pillar 315 via the portion 415-b-1 and the portion 415-b-2. Similar structures may be applied between the source line 160-b-1 and another dielectric pillar 315.

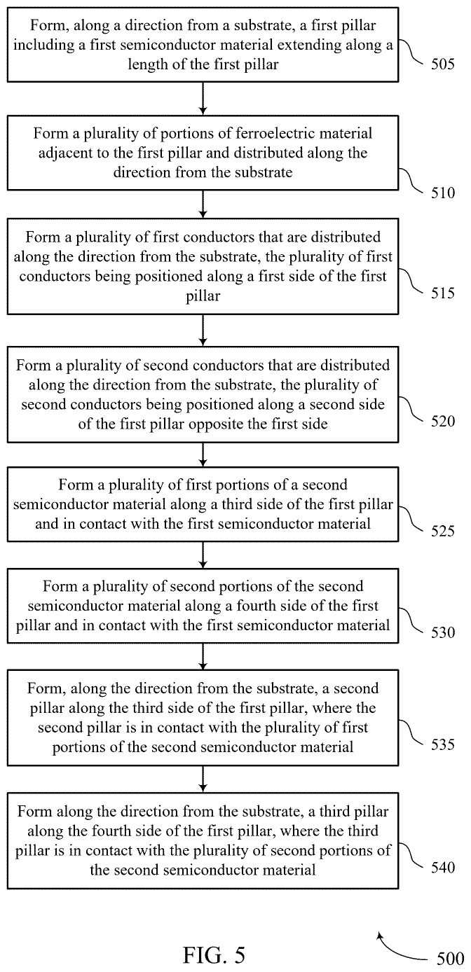

FIG. 5 shows a flowchart illustrating a method or methods 500 that supports FeNOR memory architectures in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming, along a direction from a substrate, a first pillar including a first semiconductor material extending along a length of the first pillar.

At 510, the method may include forming a plurality of portions of ferroelectric material adjacent to the first pillar and distributed along the direction from the substrate.

At 515, the method may include forming a plurality of first conductors that are distributed along the direction from the substrate, the plurality of first conductors being positioned along a first side of the first pillar.

At 520, the method may include forming a plurality of second conductors that are distributed along the direction from the substrate, the plurality of second conductors being positioned along a second side of the first pillar opposite the first side.

At 525, the method may include forming a plurality of first portions of a second semiconductor material along a third side of the first pillar and in contact with the first semiconductor material.

At 530, the method may include forming a plurality of second portions of the second semiconductor material along a fourth side of the first pillar and in contact with the first semiconductor material.

At 535, the method may include forming, along the direction from the substrate, a second pillar along the third side of the first pillar, where the second pillar is in contact with the plurality of first portions of the second semiconductor material.

At 540, the method may include forming along the direction from the substrate, a third pillar along the fourth side of the first pillar, where the third pillar is in contact with the plurality of second portions of the second semiconductor material.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming, along a direction from a substrate, a first pillar including a first semiconductor material extending along a length of the first pillar; forming a plurality of portions of ferroelectric material adjacent to the first pillar and distributed along the direction from the substrate; forming a plurality of first conductors that are distributed along the direction from the substrate, the plurality of first conductors being positioned along a first side of the first pillar; forming a plurality of second conductors that are distributed along the direction from the substrate, the plurality of second conductors being positioned along a second side of the first pillar opposite the first side; forming a plurality of first portions of a second semiconductor material along a third side of the first pillar and in contact with the first semiconductor material; forming a plurality of second portions of the second semiconductor material along a fourth side of the first pillar and in contact with the first semiconductor material; forming, along the direction from the substrate, a second pillar along the third side of the first pillar, where the second pillar is in contact with the plurality of first portions of the second semiconductor material; and forming along the direction from the substrate, a third pillar along the fourth side of the first pillar, where the third pillar is in contact with the plurality of second portions of the second semiconductor material.
Aspect 2: The method or apparatus of aspect 1, where each of the plurality of portions of the ferroelectric material is formed continuously around the first pillar before forming the plurality of first portions of the second semiconductor material and before forming the plurality of second portions of the second semiconductor material; each first portion of the second semiconductor material is formed through a respective portion of the ferroelectric material along the third side of the first pillar; and each second portion of the second semiconductor material is formed through a respective portion of the ferroelectric material along the fourth side of the first pillar.
Aspect 3: The method or apparatus of aspects 1 through 2, further including operations, features, circuitry, logic, means, or instructions, or any combination thereof for forming, along the direction from the substrate, a first cavity along the third side of the first pillar, where the second pillar is formed in the first cavity and forming, along the direction from the substrate, a second cavity along the fourth side of the first pillar opposite the first side, where the third pillar is formed in the second cavity.
Aspect 4: The method or apparatus of aspect 3, further including operations, features, circuitry, logic, means, or instructions, or any combination thereof for forming a plurality of first voids to replace a plurality of first nitride layers of a stack of nitride and oxide layers, the plurality of first voids being positioned along the first side of the first pillar, where each first conductor of the plurality of first conductors is formed in a respective first void of the plurality of first voids and forming a plurality of second voids to replace a plurality of second nitride layers of the stack of nitride and oxide layers, the plurality of second voids being positioned along the second side of the first pillar, where each second conductor of the plurality of second conductors is formed in a respective second void of the plurality of second voids.
Aspect 5: The method or apparatus of any of aspects 3 through 4, further including operations, features, circuitry, logic, means, or instructions, or any combination thereof for forming a respective first void into each first conductor of the plurality of first conductors; forming a respective second void into each second conductor of the plurality of second conductors; forming, in each respective first void, a respective first portion of a dielectric material; and forming, in each respective second void, a respective second portion of the dielectric material.
Aspect 6: The method or apparatus of any of aspects 3 through 5, where forming the second pillar and the third pillar includes operations, features, circuitry, logic, means, or instructions, or any combination thereof for forming a first portion of a barrier material along a sidewall of the first cavity and a second portion of the barrier material along a sidewall of the second cavity and forming a first portion of a conductor material within the first portion of the barrier material and a second portion of the conductor material within the second portion of the barrier material.
Aspect 7: The method or apparatus of any of aspects 3 through 6, where forming the plurality of first portions of the second semiconductor material includes operations, features, circuitry, logic, means, or instructions, or any combination thereof for forming a respective first void through each portion of the plurality of portions of the ferroelectric material to expose the first semiconductor material along the third side of the first pillar; forming the second semiconductor material in the respective first voids, where each of the plurality of first portions of the second semiconductor material are overlapping along the direction from the substrate with a first conductor of the plurality of first conductors and with a second conductor of the plurality of second conductors; forming a respective second void through each portion of the plurality of portions of the ferroelectric material to expose the first semiconductor material along the fourth side of the first pillar; and forming the second semiconductor material in the respective second voids, where each of the plurality of second portions of the second semiconductor material are overlapping along the direction from the substrate with a first conductor of the plurality of first conductors and with a second conductor of the plurality of second conductors.
Aspect 8: The method or apparatus of any of aspects 3 through 7, further including operations, features, circuitry, logic, means, or instructions, or any combination thereof for forming, along the direction from the substrate, a third cavity into a plurality of nitride layers of a stack of oxide layers and nitride layers; forming a respective void in each nitride layer of the plurality of nitride layers; and forming, into a first portion of the respective void of each nitride layer of the plurality of nitride layers, a respective portion of a dielectric material to form a plurality of portions of the dielectric material, where each portion of the plurality of portions of the dielectric material is a layer of the dielectric material that is contiguous around a respective portion of the ferroelectric material.
Aspect 9: The method or apparatus of aspect 8, where each first portion of the second semiconductor material extends through a respective portion of the dielectric material along the third side of the first pillar and each second portion of the second semiconductor material extends through a respective portion of the dielectric material along the fourth side of the first pillar.
Aspect 10: The method or apparatus of any of aspects 8 through 9, where forming the plurality of portions of the ferroelectric material of the first pillar includes operations, features, circuitry, logic, means, or instructions, or any combination thereof for recessing, into a second portion of the respective void of each nitride layer of the plurality of nitride layers, a respective portion of the plurality of portions of the ferroelectric material.
Aspect 11: The method or apparatus of aspect 10, where forming the first pillar includes operations, features, circuitry, logic, means, or instructions, or any combination thereof for forming, into the third cavity, the first semiconductor material; forming a fourth cavity into the first semiconductor material; and forming, into the fourth cavity, a core dielectric material.
Aspect 12: The method or apparatus of any of aspects 8 through 11, further including operations, features, circuitry, logic, means, or instructions, or any combination thereof for forming a second dielectric material into the third cavity and removing the dielectric material to reform the third cavity prior to forming the respective void in each nitride layer of the plurality of nitride layers.
Aspect 13: The method or apparatus of any of aspects 3 through 12, where forming the first pillar, the first cavity, and the second cavity forms the plurality of first conductors and the plurality of second conductors.
Aspect 14: The method or apparatus of any of aspects 1 through 13, further including operations, features, circuitry, logic, means, or instructions, or any combination thereof for forming, along the direction from the substrate, a fourth pillar that includes a dielectric material, where the second pillar is between the fourth pillar and the first pillar and forming, along the direction from the substrate, a fifth pillar that includes the dielectric material, where the third pillar is between the fifth pillar and the first pillar.
Aspect 15: The method or apparatus of any of aspects 1 through 14, where the first semiconductor material includes p-type doped polysilicon and the second semiconductor material includes n-type doped polysilicon.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 16: A memory device, including: a plurality of portions of a first semiconductor material; a first activation line of a memory array being positioned along a first side of each of the plurality of portions of the first semiconductor material; a second activation line of the memory array being positioned along a second side of each of the plurality of portions of the first semiconductor material opposite the first side; a plurality of first portions of a ferroelectric material, each of the plurality of first portions of the ferroelectric material being positioned between the first activation line and a respective one of the plurality of portions of the first semiconductor material and being associated with a respective first memory cell of a plurality of first memory cells of the memory array; a plurality of second portions of the ferroelectric material, each of the plurality of second portions of the ferroelectric material being positioned between the second activation line and a respective one of the plurality of portions of the first semiconductor material and being associated with a respective second memory cell of a plurality of second memory cells of the memory array; a plurality of first portions of a second semiconductor material, each of the plurality of first portions of the second semiconductor material being positioned between a respective first access line of a plurality of first access lines and a respective one of the plurality of portions of the first semiconductor material; and a plurality of second portions of the second semiconductor material, each of the plurality of second portions of the second semiconductor material being positioned between a respective second access line of a plurality of second access lines and a respective one of the plurality of portions of the first semiconductor material.
Aspect 17: The memory device of aspect 16, where: each of the plurality of first memory cells is operable to store a respective logic state based at least in part on a dipole orientation stored in a respective first portion of the plurality of first portions of the ferroelectric material; and each of the plurality of second memory cells is operable to store a respective logic state based at least in part on a dipole orientation stored in a respective second portion of the plurality of second portions of the ferroelectric material.
Aspect 18: The memory device of any of aspects 16 through 17, further including: a plurality of first portions of a dielectric material, each of the plurality of first portions of the dielectric material positioned between the first activation line and a respective one of the plurality of first portions of the ferroelectric material; and a plurality of second portions of the dielectric material, each of the plurality of second portions of the dielectric material positioned between the second activation line and a respective one of the plurality of second portions of the ferroelectric material.
Aspect 19: The memory device of any of aspects 16 through 18, where the first semiconductor material includes p-type doped polysilicon and the second semiconductor material includes n-type doped polysilicon.
Aspect 20: The memory device of any of aspects 16 through 19, where each of the plurality of portions of the first semiconductor material is around a respective portion of a dielectric material.

An apparatus is described. The following provides an overview of aspects of the apparatus as described herein:
Aspect 21: A memory device formed by a process, including: forming, along a direction from a substrate, a first pillar including a first semiconductor material extending along a length of the first pillar; forming a plurality of portions of ferroelectric material adjacent to the first pillar and distributed along the direction from the substrate; forming a plurality of first conductors that are distributed along the direction from the substrate, the plurality of first conductors being positioned along a first side of the first pillar; forming a plurality of second conductors that are distributed along the direction from the substrate, the plurality of second conductors being positioned along a second side of the first pillar opposite the first side; forming a plurality of first portions of a second semiconductor material along a third side of the first pillar and in contact with the first semiconductor material; forming a plurality of second portions of the second semiconductor material along a fourth side of the first pillar and in contact with the first semiconductor material; forming, along the direction from the substrate, a second pillar along the third side of the first pillar, where the second pillar is in contact with the plurality of first portions of the second semiconductor material; and forming along the direction from the substrate, a third pillar along the fourth side of the first pillar, where the third pillar is in contact with the plurality of second portions of the second semiconductor material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a memory device, comprising:
forming, along a direction from a substrate, a first pillar comprising a first semiconductor material extending along a length of the first pillar;
forming a plurality of portions of ferroelectric material adjacent to the first pillar and distributed along the direction from the substrate;
forming a plurality of first conductors that are distributed along the direction from the substrate, the plurality of first conductors being positioned along a first side of the first pillar;
forming a plurality of second conductors that are distributed along the direction from the substrate, the plurality of second conductors being positioned along a second side of the first pillar opposite the first side;
forming a plurality of first portions of a second semiconductor material along a third side of the first pillar and in contact with the first semiconductor material;
forming a plurality of second portions of the second semiconductor material along a fourth side of the first pillar and in contact with the first semiconductor material;
forming, along the direction from the substrate, a second pillar along the third side of the first pillar, wherein the second pillar is in contact with the plurality of first portions of the second semiconductor material; and
forming along the direction from the substrate, a third pillar along the fourth side of the first pillar, wherein the third pillar is in contact with the plurality of second portions of the second semiconductor material.

2. The method of claim 1, wherein:
each of the plurality of portions of the ferroelectric material is formed continuously around the first pillar before forming the plurality of first portions of the second semiconductor material and before forming the plurality of second portions of the second semiconductor material:
each first portion of the second semiconductor material is formed through a respective portion of the ferroelectric material along the third side of the first pillar; and
each second portion of the second semiconductor material is formed through a respective portion of the ferroelectric material along the fourth side of the first pillar.

3. The method of claim 1, further comprising:
forming, along the direction from the substrate, a first cavity along the third side of the first pillar, wherein the second pillar is formed in the first cavity; and
forming, along the direction from the substrate, a second cavity along the fourth side of the first pillar opposite the first side, wherein the third pillar is formed in the second cavity.

4. The method of claim 3, further comprising:
forming a plurality of first voids to replace a plurality of first nitride layers of a stack of nitride and oxide layers, the plurality of first voids being positioned along the first side of the first pillar, wherein each first conductor of the plurality of first conductors is formed in a respective first void of the plurality of first voids; and
forming a plurality of second voids to replace a plurality of second nitride layers of the stack of nitride and oxide layers, the plurality of second voids being positioned along the second side of the first pillar, wherein each second conductor of the plurality of second conductors is formed in a respective second void of the plurality of second voids.

5. The method of claim 3, further comprising:
forming a respective first void into each first conductor of the plurality of first conductors;
forming a respective second void into each second conductor of the plurality of second conductors;
forming, in each respective first void, a respective first portion of a dielectric material; and
forming, in each respective second void, a respective second portion of the dielectric material.

6. The method of claim 3, wherein forming the second pillar and the third pillar comprises:
forming a first portion of a barrier material along a sidewall of the first cavity and a second portion of the barrier material along a sidewall of the second cavity; and
forming a first portion of a conductor material within the first portion of the barrier material and a second portion of the conductor material within the second portion of the barrier material.

7. The method of claim 3, wherein forming the plurality of first portions of the second semiconductor material comprises:
forming a respective first void through each portion of the plurality of portions of the ferroelectric material to expose the first semiconductor material along the third side of the first pillar;
forming the second semiconductor material in the respective first voids, wherein each of the plurality of first portions of the second semiconductor material are overlapping along the direction from the substrate with a first conductor of the plurality of first conductors and with a second conductor of the plurality of second conductors;
forming a respective second void through each portion of the plurality of portions of the ferroelectric material to expose the first semiconductor material along the fourth side of the first pillar; and
forming the second semiconductor material in the respective second voids, wherein each of the plurality of second portions of the second semiconductor material are overlapping along the direction from the substrate with a first conductor of the plurality of first conductors and with a second conductor of the plurality of second conductors.

8. The method of claim 3, further comprising:
forming, along the direction from the substrate, a third cavity into a plurality of nitride layers of a stack of oxide layers and nitride layers;
forming a respective void in each nitride layer of the plurality of nitride layers; and
forming, into a first portion of the respective void of each nitride layer of the plurality of nitride layers, a respective portion of a dielectric material to form a plurality of portions of the dielectric material, wherein each portion of the plurality of portions of the dielectric material is a layer of the dielectric material that is contiguous around a respective portion of the ferroelectric material.

9. The method of claim 8, wherein:
each first portion of the second semiconductor material extends through a respective portion of the dielectric material along the third side of the first pillar, and
each second portion of the second semiconductor material extends through a respective portion of the dielectric material along the fourth side of the first pillar.

10. The method of claim 8, wherein forming the plurality of portions of the ferroelectric material of the first pillar comprises:
recessing, into a second portion of the respective void of each nitride layer of the plurality of nitride layers, a respective portion of the plurality of portions of the ferroelectric material.

11. The method of claim 10, wherein forming the first pillar comprises:
forming, into the third cavity, the first semiconductor material;
forming a fourth cavity into the first semiconductor material; and
forming, into the fourth cavity, a core dielectric material.

12. The method of claim 8, further comprising:
forming a second dielectric material into the third cavity; and
removing the dielectric material to reform the third cavity prior to forming the respective void in each nitride layer of the plurality of nitride layers.

13. The method of claim 3, wherein forming the first pillar, the first cavity, and the second cavity forms the plurality of first conductors and the plurality of second conductors.

14. The method of claim 1, further comprising:
forming, along the direction from the substrate, a fourth pillar that comprises a dielectric material, wherein the second pillar is between the fourth pillar and the first pillar; and
forming, along the direction from the substrate, a fifth pillar that comprises the dielectric material, wherein the third pillar is between the fifth pillar and the first pillar.

15. The method of claim 1, wherein the first semiconductor material comprises p-type doped polysilicon and the second semiconductor material comprises n-type doped polysilicon.

16. A memory device, comprising:
a plurality of portions of a first semiconductor material;
a first activation line of a memory array being positioned along a first side of each of the plurality of portions of the first semiconductor material;
a second activation line of the memory array being positioned along a second side of each of the plurality of portions of the first semiconductor material opposite the first side;
a plurality of first portions of a ferroelectric material, each of the plurality of first portions of the ferroelectric material being positioned between the first activation line and a respective one of the plurality of portions of the first semiconductor material and being associated with a respective first memory cell of a plurality of first memory cells of the memory array;
a plurality of second portions of the ferroelectric material, each of the plurality of second portions of the ferroelectric material being positioned between the second activation line and a respective one of the plurality of portions of the first semiconductor material and being associated with a respective second memory cell of a plurality of second memory cells of the memory array;
a plurality of first portions of a second semiconductor material, each of the plurality of first portions of the second semiconductor material being positioned between a respective first access line of a plurality of first access lines and a respective one of the plurality of portions of the first semiconductor material; and
a plurality of second portions of the second semiconductor material, each of the plurality of second portions of the second semiconductor material being positioned between a respective second access line of a plurality of second access lines and a respective one of the plurality of portions of the first semiconductor material.

17. The memory device of claim 16, wherein:
each of the plurality of first memory cells is operable to store a respective logic state based at least in part on a dipole orientation stored in a respective first portion of the plurality of first portions of the ferroelectric material; and
each of the plurality of second memory cells is operable to store a respective logic state based at least in part on a dipole orientation stored in a respective second portion of the plurality of second portions of the ferroelectric material.

18. The memory device of claim 16, further comprising:
a plurality of first portions of a dielectric material, each of the plurality of first portions of the dielectric material positioned between the first activation line and a respective one of the plurality of first portions of the ferroelectric material; and
a plurality of second portions of the dielectric material, each of the plurality of second portions of the dielectric material positioned between the second activation line and a respective one of the plurality of second portions of the ferroelectric material.

19. The memory device of claim 16, wherein the first semiconductor material comprises p-type doped polysilicon and the second semiconductor material comprises n-type doped polysilicon.

20. The memory device of claim 16, wherein each of the plurality of portions of the first semiconductor material is around a respective portion of a dielectric material.

21. A memory device formed by a process, comprising:
forming, along a direction from a substrate, a first pillar comprising a first semiconductor material extending along a length of the first pillar;
forming a plurality of portions of ferroelectric material adjacent to the first pillar and distributed along the direction from the substrate;
forming a plurality of first conductors that are distributed along the direction from the substrate, the plurality of first conductors being positioned along a first side of the first pillar;
forming a plurality of second conductors that are distributed along the direction from the substrate, the plurality of second conductors being positioned along a second side of the first pillar opposite the first side;
forming a plurality of first portions of a second semiconductor material along a third side of the first pillar and in contact with the first semiconductor material;
forming a plurality of second portions of the second semiconductor material along a fourth side of the first pillar and in contact with the first semiconductor material;
forming, along the direction from the substrate, a second pillar along the third side of the first pillar, wherein the second pillar is in contact with the plurality of first portions of the second semiconductor material; and
forming along the direction from the substrate, a third pillar along the fourth side of the first pillar, wherein the third pillar is in contact with the plurality of second portions of the second semiconductor material.
